(19) United States
(12) Patent Application Publication
(10) Pub. No.: US 2026/0121373 A1
(43) Pub. Date: Apr. 30, 2026

(54) LIGHT EMITTING DEVICE AND METHOD FOR MANUFACTURING THE SAME

(71) Applicant: SONY SEMICONDUCTOR SOLUTIONS CORPORATION, Kanagawa (JP)

(72) Inventor: Atsushi YAMAMOTO, Kanagawa (JP)

(73) Assignee: SONY SEMICONDUCTOR SOLUTIONS CORPORATION, Kanagawa (JP)

(21) Appl. No.: 18/259,423

(22) PCT Filed: Dec. 8, 2021
(86) PCT No.: PCT/JP2021/045170

§ 371 Date: Jun. 27, 2023

(30) Foreign Application Priority Data
Jan. 4, 2021 (JP) 2021-000267

(51) Int. Cl. H01S 5/02253; H01S 5/02; H01S 5/0239

(52) U.S. Cl. CPC H01S 5/02253; H01S 5/0206; H01S 5/0239

(57) ABSTRACT

A light emitting device capable of shaping light from light emitting elements, and a manufacturing method. A light emitting device of the present disclosure includes: a substrate; a plurality of light emitting elements on a first surface side of the substrate; one or more front lenses on a second surface side of the substrate; and one or more rear lenses on a film on a front surface of the first lens and on which light having passed through the first lens is incident, in which the front lens includes a first lens and a second lens, and a part of a front surface of the second lens constitutes a front surface of the first lens, or the rear lens includes a third lens and a fourth lens, and a part of a front surface of the fourth lens constitutes a front surface of the third lens.

### TECHNICAL FIELD

The present disclosure relates to a light emitting device and a method for manufacturing the same.

### BACKGROUND ART

As a type of semiconductor laser, a surface emitting laser such as a vertical cavity surface emitting laser (VCSEL) is known. In general, in a light emitting device using a surface emitting laser, a plurality of light emitting elements is provided in a two-dimensional array on a front surface or a back surface of a substrate.

### CITATION LIST

### Patent Document

Patent Document 1: Japanese Patent Application Laid-Open No. 2004-526194

### SUMMARY OF THE INVENTION

### Problems to be Solved by the Invention

In the light emitting device as described above, for example, it is necessary to shape light emitted from a plurality of light emitting elements into light (for example, parallel light) having a desired shape. In this case, in order to suitably shape light, how to shape light is a problem.

Therefore, the present disclosure provides a light emitting device capable of suitably shaping light from a plurality of light emitting elements, and a method for manufacturing the same.

### Solutions to Problems

A light emitting device according to a first aspect of the present disclosure includes: a substrate; a plurality of light emitting elements provided on a first surface side of the substrate; one or more front lenses which are provided on a second surface side of the substrate and on which light emitted from the plurality of light emitting elements is incident; and one or more rear lenses which are provided on a film provided on a front surface of the first lens and on which light having passed through the first lens is incident, in which the front lens includes a first lens and a second lens, and a part of a front surface of the second lens constitutes a front surface of the first lens, or the rear lens includes a third lens and a fourth lens, and a part of a front surface of the fourth lens constitutes a front surface of the third lens. Accordingly, for example, the light from the plurality of light emitting elements can be suitably collimated using the front lens and the rear lens, and the light from the plurality of light emitting elements can be suitably shaped. For example, light can be collimated by only the front lens and the rear lens without using a correction lens above the substrate, or the number of correction lenses used together with the front lens and the rear lens for collimating light can be reduced. As a result, the light emitting device can be reduced in size or height.

Further, in the first aspect, the first lens may be provided in the second lens in plan view, or the third lens may be provided in the fourth lens in plan view. Accordingly, for example, the first lens can be accommodated in the installation region of the second lens, and the third lens can be accommodated in the installation region of the fourth lens. As a result, these lenses can be disposed in a small region.

Further, in the first aspect, the light emitting element and the first or third lens may have a correspondence ratio of 1:1, and the light emitting element and the second or fourth lens may have a correspondence ratio of N:1 (N is an integer of 2 or more). Accordingly, for example, the light from the plurality of light emitting elements can be shaped by a lens for each light emitting element, and the light from the plurality of light emitting elements can be collectively shaped by a lens for every two or more light emitting elements.

Further, in the first aspect, the front lens may include the first lens and the second lens, and the rear lens may include the third lens and the fourth lens. Accordingly, for example, light can be shaped by two types of lenses in the front lens, and light can be shaped by two types of lenses in the rear lens.

Further, in the first aspect, the front lens may include a lens having a correspondence ratio of Na:1 with the light emitting element, and the rear lens may include a lens having a correspondence ratio of Nb:1 with the light emitting element (Na and Nb are integers of 2 or more different from each other). Accordingly, for example, the unit of the number of light emitting elements that collectively shape light can be made different between the front lens and the rear lens.

Further, in the first aspect, the value of Nb may be larger than the value of Na. Accordingly, for example, the unit of the number of light emitting elements that collectively shape light can be made larger in the rear lens than in the front lens. As a result, individual shaping can be performed by the front lens, and then comprehensive shaping can be performed by the rear lens.

Further, in the first aspect, the first, second, third, or fourth lens may include at least one of a convex lens, a concave lens, a flat lens, or a binary lens. Accordingly, for example, it is possible to shape light with an appropriate lens according to the purpose of use of light.

Further, in the first aspect, the front lens may be provided on the second surface of the substrate as a part of the substrate. Accordingly, for example, the front lens can be easily formed by processing the substrate.

Further, in the first aspect, the substrate may be a semiconductor substrate containing gallium (Ga) and arsenic (As). This makes it possible to make the substrate suitable for the light emitting device.

Further, in the first aspect, light emitted from the plurality of light emitting elements may pass through the substrate from the first surface to the second surface and enter the front lens. This makes it possible to realize, for example, a structure in which light passes through the substrate and is emitted from the light emitting device.

Further, in the first aspect, the first surface of the substrate may be a front surface of the substrate, and the second surface of the substrate may be a back surface of the substrate. This makes it possible, for example, to make the light emitting device a back emission type.

Further, the light emitting device of the first aspect may further include a drive device that is provided on the first surface side of the substrate via the plurality of light emitting elements and drives the plurality of light emitting elements. Accordingly, for example, the substrate provided with the light emitting element can be loaded on the drive device.

Further, in the first aspect, the drive device may drive the plurality of light emitting elements for each light emitting element. Accordingly, for example, the light emitted from the plurality of light emitting elements can be more precisely controlled.

A light emitting device according to a second aspect of the present disclosure includes: a substrate; a plurality of light emitting elements provided on a first surface side of the substrate; and one or more lenses which are provided on a second surface side of the substrate and on which light emitted from the plurality of light emitting elements is incident, in which the lens includes a fifth lens and a sixth lens, and a part of a front surface of the sixth lens constitutes a front surface of the fifth lens. Accordingly, for example, the light from the plurality of light emitting elements can be suitably collimated using the fifth lens and the sixth lens, and the light from the plurality of light emitting elements can be suitably shaped. For example, light can be collimated by only the fifth lens and the sixth lens without using a correction lens above the substrate, or the number of correction lenses used together with the fifth lens and the sixth lens for collimating light can be reduced. As a result, the light emitting device can be reduced in size or height.

Further, in the second aspect, the fifth and sixth lenses may be provided on the second surface of the substrate as a part of the substrate. Accordingly, for example, the lens can be easily formed by processing the substrate.

Further, in the second aspect, the fifth and sixth lenses may be provided on a film provided on the second surface side of the substrate. Accordingly, for example, the lens can be formed without processing the substrate itself.

A method for manufacturing a light emitting device according to a third aspect of the present disclosure includes: forming a plurality of light emitting elements on a first surface side of a substrate; forming, on a second surface side of the substrate, one or more front lenses on which light emitted from the plurality of light emitting elements is incident; and forming, on a film provided on a front surface of the front lens, one or more rear lenses on which light having passed through the front lens is incident, in which the front lens includes a first lens and a second lens, and is formed such that a part of a front surface of the second lens constitutes a front surface of the first lens, or the rear lens includes a third lens and a fourth lens, and is formed such that a part of a front surface of the fourth lens constitutes a front surface of the third lens. Accordingly, for example, the light from the plurality of light emitting elements can be suitably collimated using the front lens and the rear lens, and the light from the plurality of light emitting elements can be suitably shaped. For example, light can be collimated by only the front lens and the rear lens without using a correction lens above the substrate, or the number of correction lenses used together with the front lens and the rear lens for collimating light can be reduced. As a result, the light emitting device can be reduced in size or height.

Further, in the third aspect, the first lens may be formed after formation of the second lens, or the third lens may be formed after formation of the fourth lens. Accordingly, for example, the lenses can be precisely formed.

Further, in the third aspect, the first lens may be formed simultaneously with the second lens, or the third lens may be formed simultaneously with the fourth lens. Accordingly, for example, the number of steps for forming the lenses can be reduced.

Further, in the third aspect, the front lens may be formed as a part of the substrate by processing the second surface of the substrate. Accordingly, for example, the lens can be easily formed by processing the substrate.

### BRIEF DESCRIPTION OF DRAWINGS

FIG. 1 is a block diagram illustrating a configuration of a distance measuring apparatus of a first embodiment.

FIG. 2 is a cross-sectional view illustrating an example of a structure of a light emitting device of the first embodiment.

FIG. 3 is a cross-sectional view illustrating a structure of the light emitting device illustrated in B of FIG. 2.

FIG. 4 is a cross-sectional view illustrating a structure of the light emitting device of the first embodiment.

FIG. 5 is a plan view illustrating an example of a structure of the light emitting device of the first embodiment.

FIG. 6 is a cross-sectional view illustrating a structure of the light emitting device of a modification of the first embodiment.

FIG. 7 is a cross-sectional view illustrating a structure of the light emitting device of another modification of the first embodiment.

FIG. 8 is a cross-sectional view illustrating a structure of the light emitting device of another modification of the first embodiment.

FIG. 9 is a cross-sectional view illustrating a structure of the light emitting device of another modification of the first embodiment.

FIG. 10 is a cross-sectional view (1/4) illustrating a method for manufacturing the light emitting device of the first embodiment.

FIG. 11 is a cross-sectional view (2/4) illustrating the method for manufacturing the light emitting device of the first embodiment.

FIG. 12 is a cross-sectional view (3/4) illustrating the method for manufacturing the light emitting device of the first embodiment.

FIG. 13 is a cross-sectional view (4/4) illustrating the method for manufacturing the light emitting device of the first embodiment.

FIG. 14 is a cross-sectional view (1/2) illustrating a method for manufacturing the light emitting device of a modification of the first embodiment.

FIG. 15 is a cross-sectional view (2/2) illustrating the method for manufacturing the light emitting device of the modification of the first embodiment.

FIG. 16 is a cross-sectional view illustrating a structure of a light emitting device of a second embodiment.

FIG. 17 is a plan view illustrating an example of a structure of the light emitting device of the second embodiment.

FIG. 18 is a plan view illustrating another example of the structure of the light emitting device of the second embodiment.

FIG. 19 is a cross-sectional view illustrating a structure of a light emitting device of a third embodiment.

FIG. 20 is a cross-sectional view illustrating a structure of the light emitting device of a modification of the third embodiment.

### MODE FOR CARRYING OUT THE INVENTION

Hereinafter, embodiments of the present disclosure will be described with reference to the drawings.

### First Embodiment

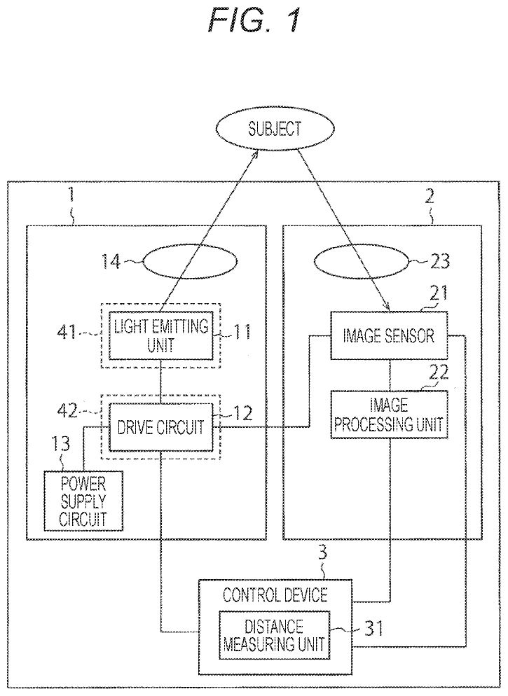

FIG. 1 is a block diagram illustrating a configuration of a distance measuring apparatus of a first embodiment.

The distance measuring apparatus in FIG. 1 includes a light emitting device 1, an imaging device 2, and a control device 3. The distance measuring apparatus in FIG. 1 irradiates a subject with light emitted from the light emitting device 1. The imaging device 2 receives light reflected by the subject to capture an image of the subject. The control device 3 measures (calculates) the distance to the subject using an image signal output from the imaging device 2. The light emitting device 1 functions as a light source for the imaging device 2 to capture an image of a subject.

The light emitting device 1 includes a light emitting unit 11, a drive circuit 12, a power supply circuit 13, and a light-emitting side optical system 14. The imaging device 2 includes an image sensor 21, an image processing unit 22, and an imaging side optical system 23. The control device 3 includes a distance measuring unit 31.

The light emitting unit 11 emits laser light for irradiating the subject. As will be described later, the light emitting unit 11 of the present embodiment includes a plurality of light emitting elements arranged in a two-dimensional array, and each light emitting element has a VCSEL structure. The subject is irradiated with light emitted from these light emitting elements. The light emitting unit 11 of the present embodiment is provided in a chip called a laser diode (LD) chip 41.

The drive circuit 12 is an electric circuit that drives the light emitting unit 11, and the power supply circuit 13 is an electric circuit that generates a power supply voltage of the drive circuit 12. In the present embodiment, for example, the power supply circuit 13 generates a power supply voltage from an input voltage supplied from a battery in the distance measuring apparatus, and the drive circuit 12 drives the light emitting unit 11 using the power supply voltage. The drive circuit 12 of the present embodiment is provided in a substrate called a laser diode driver (LDD) substrate 42.

The light-emitting side optical system 14 includes various optical elements, and irradiates a subject with light from the light emitting unit 11 via these optical elements. Similarly, the imaging side optical system 23 includes various optical elements, and receives light from a subject via these optical elements.

The image sensor 21 receives light from a subject via the imaging side optical system 23, and converts the light into an electric signal by photoelectric conversion. The image sensor 21 is, for example, a charge coupled device (CCD) sensor or a complementary metal oxide semiconductor (CMOS) sensor. The image sensor 21 of the present embodiment converts the electronic signal from an analog signal to a digital signal by analog to digital (A/D) conversion, and outputs an image signal as a digital signal to the image processing unit 22. Further, the image sensor 21 of the present embodiment outputs a frame synchronization signal to the drive circuit 12, and the drive circuit 12 causes the light emitting unit 11 to emit light at a timing corresponding to the frame period in the image sensor 21 on the basis of the frame synchronization signal.

The image processing unit 22 performs various types of image processing on the image signal output from the image sensor 21. The image processing unit 22 includes, for example, an image processing processor such as a digital signal processor (DSP).

The control device 3 controls various operations of the distance measuring apparatus in FIG. 1, and controls, for example, a light emitting operation of the light emitting device 1 and an imaging operation of the imaging device 2. The control device 3 includes, for example, a central processing unit (CPU), a read only memory (ROM), a random access memory (RAM), and the like.

The distance measuring unit 31 measures the distance to the subject on the basis of the image signal output from the image sensor 21 and subjected to the image processing by the image processing unit 22. The distance measuring unit 31 employs, for example, a structured light (STL) method or a time of flight (ToF) method as a distance measurement method. The distance measuring unit 31 may further measure the distance between the distance measuring apparatus and the subject for each portion of the subject on the basis of the image signal to specify the three-dimensional shape of the subject.

### (1) Structure of Light Emitting Device 1 of First Embodiment

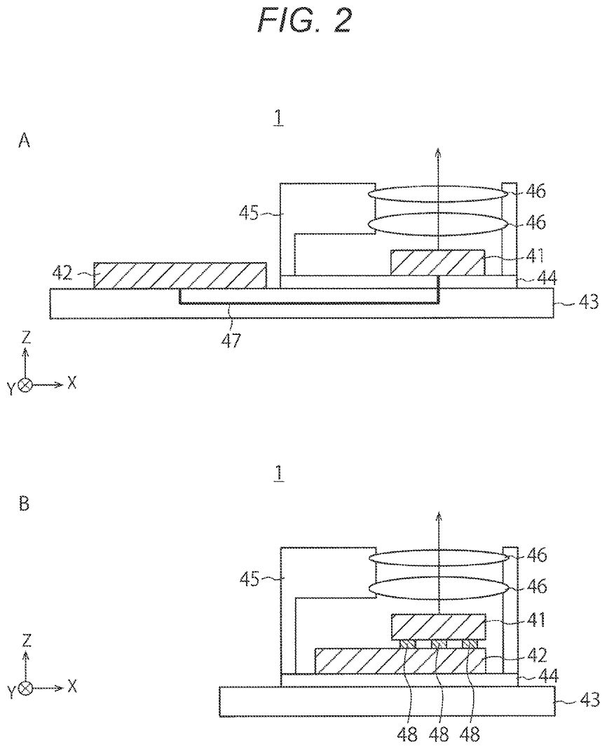

FIG. 2 is a cross-sectional view illustrating an example of a structure of the light emitting device 1 of the first embodiment.

A of FIG. 2 illustrates a first example of the structure of the light emitting device 1 of the present embodiment. The light emitting device 1 of this example includes the above-described LD chip 41 and LDD substrate 42, a mounting substrate 43, a heat dissipation substrate 44, a correction lens holding portion 45, one or more correction lenses 46, and a wiring 47.

A of FIG. 2 illustrates an X axis, a Y axis, and a Z axis perpendicular to each other. The X direction and the Y direction correspond to a lateral direction (horizontal direction), and the Z direction corresponds to a longitudinal direction (vertical direction). Further, the +Z direction corresponds to the upward direction, and the −Z direction corresponds to the downward direction. The −Z direction may strictly match the gravity direction, or may not strictly match the gravity direction.

The LD chip 41 is disposed on the mounting substrate 43 via the heat dissipation substrate 44, and the LDD substrate 42 is also disposed on the mounting substrate 43. The mounting substrate 43 is, for example, a printed circuit board. The image sensor 21 and the image processing unit 22 in FIG. 1 are also disposed on the mounting substrate 43 of the present embodiment. The heat dissipation substrate 44 is, for example, a ceramic substrate such as an aluminum oxide substrate or an aluminum nitride substrate.

The correction lens holding portion 45 is disposed on the heat dissipation substrate 44 so as to surround the LD chip 41, and holds one or more correction lenses 46 above the LD chip 41. These correction lenses 46 are included in the above-described light-emitting side optical system 14 (FIG. 1). The light emitted from the light emitting unit 11 (FIG. 1) in the LD chip 41 is corrected by these correction lenses 46 and then applied to the subject (FIG. 1). A of FIG. 2 illustrates two correction lenses 46 held by the correction lens holding portion 45 as an example.

The wiring 47 is provided on the front surface, the back surface, the inside, or the like of the mounting substrate 43, and electrically connects the LD chip 41 and the LDD substrate 42. The wiring 47 is, for example, a printed wiring provided on the front surface or the back surface of the mounting substrate 43 or a via wiring penetrating the mounting substrate 43. The wiring 47 of the present embodiment further passes through the inside or the vicinity of the heat dissipation substrate 44.

B of FIG. 2 illustrates a second example of the structure of the light emitting device 1 of the present embodiment. The light emitting device 1 of this example includes the same components as those of the light emitting device 1 of the first example, but includes bumps 48 instead of the wiring 47.

In B of FIG. 2, the LDD substrate 42 is disposed on the heat dissipation substrate 44, and the LD chip 41 is disposed on the LDD substrate 42. By disposing the LD chip 41 on the LDD substrate 42 in this way, the size of the mounting substrate 43 can be reduced as compared with the case of the first example. In B of FIG. 2, the LD chip 41 is disposed on the LDD substrate 42 via the bumps 48, and is electrically connected to the LDD substrate 42 by the bumps 48.

Hereinafter, the light emitting device 1 of the present embodiment will be described as having the structure of the second example illustrated in B of FIG. 2. However, the following description is also applicable to the light emitting device 1 having the structure of the first example except for the description of the structure specific to the second example.

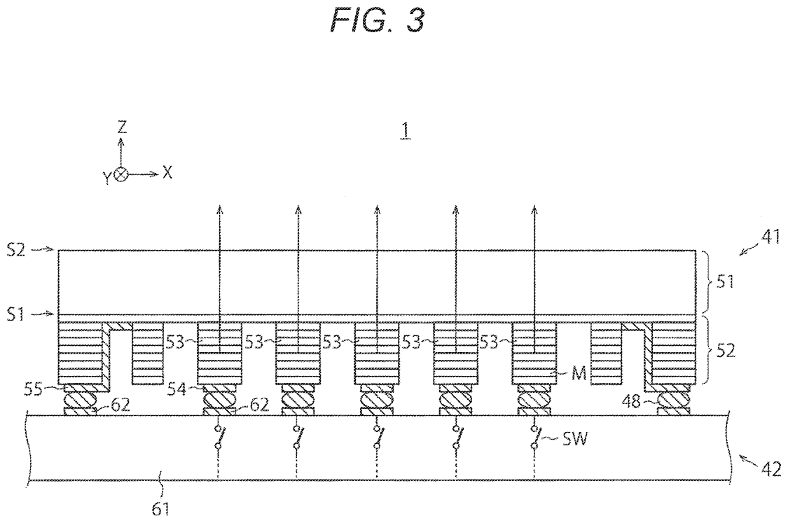

FIG. 3 is a cross-sectional view illustrating a structure of the light emitting device 1 illustrated in B of FIG. 2.

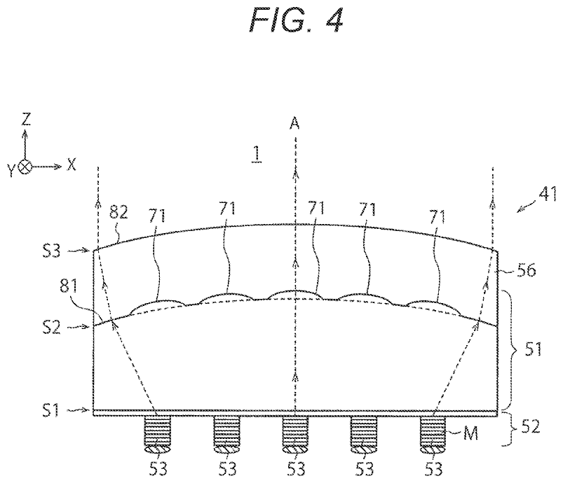

FIG. 3 illustrates cross sections of the LD chip 41 and the LDD substrate 42 in the light emitting device 1. As illustrated in FIG. 3, the LD chip 41 includes a substrate 51, a laminated film 52, a plurality of light emitting elements 53, a plurality of anode electrodes 54, and a plurality of cathode electrodes 55, and the LDD substrate 42 includes a substrate 61 and a plurality of connection pads 62. Note that, in FIG. 3, illustration of lenses 71, 81, and 82 to be described later is omitted (see FIG. 4).

The substrate 51 is, for example, a semiconductor substrate such as a gallium arsenide (GaAs) substrate. FIG. 3 illustrates a front surface S1 of the substrate 51 facing the −Z direction and a back surface S2 of the substrate 51 facing the +Z direction. The front surface S1 is an example of a first surface of the present disclosure, and the back surface S2 is an example of a second surface of the present disclosure.

The laminated film 52 includes a plurality of layers laminated on the front surface S1 of the substrate 51. Examples of these layers include an n-type semiconductor layer, an active layer, a p-type semiconductor layer, a light reflecting layer, an insulating layer having a light emission window, and the like. The laminated film 52 includes a plurality of mesa portions M protruding in the −Z direction. A part of the mesa portions M constitutes a plurality of light emitting elements 53.

The light emitting element 53 is provided on the front surface S1 side of the substrate 51 as a part of the laminated film 52. The light emitting element 53 of the present embodiment has a VCSEL structure and emits light in the +Z direction. As illustrated in FIG. 3, the light emitted from the light emitting element 53 passes through the substrate 51 from the front surface S1 to the back surface S2, and enters the correction lens 46 (FIG. 2) from the substrate 51. In this way, the LD chip 41 of the present embodiment is a back emission type VCSEL chip.

The anode electrode 54 is formed on the lower surface of the light emitting element 53. The cathode electrode 55 is formed on the lower surface of the mesa portion M other than the light emitting element 53, and extends to the lower surface of the laminated film 52 existing between the mesa portions M. Each light emitting element 53 emits light when a current flows between the corresponding anode electrode 54 and the corresponding cathode electrode 55.

As described above, the LD chip 41 is disposed on the LDD substrate 42 via the bumps 48, and is electrically connected to the LDD substrate 42 by the bumps 48. Specifically, the connection pad 62 is formed on the substrate 61 included in the LDD substrate 42, and the mesa portion M is disposed on the connection pad 62 via the bump 48. Each mesa portion M is disposed on the bump 48 via the anode electrode 54 or the cathode electrode 55. The substrate 61 is, for example, a semiconductor substrate such as a silicon (Si) substrate.

The LDD substrate 42 includes the drive circuit 12 that drives the light emitting unit 11 (FIG. 1). FIG. 3 schematically illustrates a plurality of switches SW included in the drive circuit 12. Each switch SW is electrically connected to the corresponding light emitting element 53 via the bump 48. The drive circuit 12 of the present embodiment can control (turn on and off) these switches SW for each switch SW. Therefore, the drive circuit 12 can drive the plurality of light emitting elements 53 for each light emitting element 53. This makes it possible to precisely control the light emitted from the light emitting unit 11, for example, by causing only the light emitting element 53 necessary for distance measurement to emit light. Such individual control of the light emitting elements 53 can be realized by disposing the LDD substrate 42 below the LD chip 41, so that each light emitting element 53 is easily electrically connected to the corresponding switch SW. The LDD substrate 42 is an example of a drive device of the present disclosure.

FIG. 4 is a cross-sectional view illustrating a structure of the light emitting device 1 of the first embodiment.

FIG. 4 illustrates a cross section of the LD chip 41 in the light emitting device 1. As described above, the LD chip 41 includes the substrate 51, the laminated film 52, the plurality of light emitting elements 53, the plurality of anode electrodes 54, and the plurality of cathode electrodes 55, and further includes a lens film 56. However, in FIG. 4, illustration of the anode electrode 54 and the cathode electrode 55 is omitted. The lens film 56 is an example of a film of the present disclosure.

The LD chip 41 of the present embodiment includes the plurality of light emitting elements 53 on the front surface S1 side of the substrate 51, and a plurality of lower small lenses 71, a lower large lens 81, and an upper large lens 82 on the back surface S2 side of the substrate 51. The lower small lens 71 and the lower large lens 81 are examples of a front lens of the present disclosure, and the upper large lens 82 is an example of a rear lens of the present disclosure. Further, the lower small lens 71 is an example of a first lens of the present disclosure, and the lower large lens 81 is an example of a second lens of the present disclosure.

The lower small lens 71 and the lower large lens 81 are provided on the back surface S2 of the substrate 51 as a part of the substrate 51. The lower large lens 81 of the present embodiment is a large convex lens protruding in the +Z direction on the back surface S2 of the substrate 51, and the lower small lens 71 of the present embodiment is a small convex lens protruding in the +Z direction on the front surface of the lower large lens 81 in the back surface S2 of the substrate 51. Therefore, in the present embodiment, a part of the front surface of the lower large lens 81 constitutes the front surface of the lower small lens 71. The lower small lens 71 and the lower large lens 81 of the present embodiment are formed by processing the substrate 51 from the back surface S2. According to the present embodiment, the lower small lens 71 and the lower large lens 81 can be easily formed by processing the substrate 51. Note that the lower small lens 71 and the lower large lens 81 may be provided on another lens film provided between the substrate 51 and the lens film 56 instead of being provided on the substrate 51.

The upper large lens 82 is provided on a front surface (upper surface) S3 of the lens film 56 as a part of the lens film 56. The lens film 56 is provided on the front surface of the lower small lens 71 and the front surface of the lower large lens 81 on the back surface S2 side of the substrate 51. The lens film 56 includes a material different from that of the substrate 51, and includes, for example, a material that is transparent to light from the light emitting element 53 and has a refractive index different from that of the substrate 51. The lens film 56 is, for example, an inorganic film such as a silicon oxide film (SiO₂ film), a silicon oxynitride film (SiON film), a silicon nitride film (SiN film), a silicon oxycarbide film (SiOC film), a silicon carbide film (SiC film), or an amorphous silicon (Si) film, or an organic film. The upper large lens 82 of the present embodiment is a large convex lens protruding in the +Z direction on the front surface S3 of the lens film 56.

Similarly to the light emitting element 53, the lower small lenses 71 are arranged in a two-dimensional array. The light emitting element 53 and the lower small lens 71 of the present embodiment have a correspondence ratio of 1:1, and each lower small lens 71 is disposed in the +Z direction of one light emitting element 53. On the other hand, the light emitting element 53 and the lower large lens 81 of the present embodiment have a correspondence ratio of N:1 (N is an integer of 2 or more), and one lower large lens 81 is disposed in the +Z direction of the N light emitting elements 53. Similarly, the light emitting element 53 and the upper large lens 82 of the present embodiment have a correspondence ratio of N:1, and one upper large lens 82 is disposed in the +Z direction of the N light emitting elements 53.

The light emitted from the plurality of light emitting elements 53 passes through the substrate 51 from the front surface S1 to the back surface S2, and enters the plurality of lower small lenses 71 and the lower large lens 81. For example, the light emitted from each light emitting element 53 enters the corresponding lower small lens 71. The light having passed through the lower small lenses 71 and the lower large lens 81 enters the upper large lens 82. The light having passed through the upper large lens 82 enters the correction lens 46 (FIG. 2). The correction lens 46 of the present embodiment is disposed above the substrate 51 and the lens film 56, and includes a lens material separated from the substrate 51 and the lens film 56.

In the present embodiment, the lower small lens 71, the lower large lens 81, the upper large lens 82, and the correction lens 46 focus the light from the light emitting element 53, and further collimate the light into parallel light. For example, the lower small lens 71 and the lower large lens 81 focus light from the light emitting element 53, and the upper large lens 82 and the correction lens 46 collimate light from the lower small lens 71 and the lower large lens 81 into parallel light. The subject (FIG. 1) is irradiated with the light passing through the correction lens 46. Note that, in a case where light can be sufficiently collimated by only the upper large lens 82, the correction lens 46 may not be provided in the light emitting device 1. In this case, the subject is irradiated with light passing through the upper large lens 82.

Note that the light emitting device 1 of the present embodiment may include an antireflection film provided on the lens film 56. The antireflection film is provided, for example, on the front surface of the upper large lens 82 and the front surface S3 of the lens film 56 other than the front surface of the upper large lens 82. This makes it possible to suppress reflection of light on the front surface S3 of the lens film 56.

In addition, the light emitting device 1 of the present embodiment may include an inorganic film (for example, a light shielding film or a reflective film) provided on the lens film 56. This inorganic film is provided, for example, on the front surface S3 of the lens film 56 other than the front surface of the upper large lens 82. This makes it possible to suppress light from passing through the front surface S3 of the lens film 56 other than the upper large lens 82.

Hereinafter, with continued reference to FIG. 4, the operations and effects of the light emitting device 1 of the present embodiment will be described in more detail.

FIG. 4 illustrates an optical center (central axis) A of the lower large lens 81, the upper large lens 82, and the correction lens 46 (FIG. 2). In FIG. 4, the front surface S1 of the substrate 51 is parallel to the XY plane, and the optical center A is parallel to the Z direction.

The light emitting device 1 of the present embodiment includes the lower small lens 71 provided on the back surface S2 of the substrate 51, the lower large lens 81 provided on the back surface S2 of the substrate 51, and the upper large lens 82 provided on the front surface S3 of the lens film 56. This makes it possible to reduce the aberration of the correction lens 46. The reason is that the lower large lens 81 and the upper large lens 82 suppress spread of light emitted from the lower small lens 71 far from the optical center A as compared with spread of light emitted from the lower small lens 71 close to the optical center A, and the correction lens 46 easily collimates the light from the lower small lens 71. This makes it possible to realize the imaging device 2 (FIG. 1) with high resolution.

If the lower large lens 81 and the upper large lens 82 are not provided, the spread of light emitted from the lower small lens 71 far from the optical center A is substantially the same as the spread of light emitted from the lower small lens 71 close to the optical center A. As a result, the correction lens 46 is less likely to collimate the light from the lower small lens 71 than in the case of the present embodiment, and aberration occurs in the correction lens 46. Specifically, the parallelism of the light emitted from the vicinity of the end portion of the correction lens 46 deteriorates, and blurring or distortion occurs at the end portion of the image. On the other hand, according to the present embodiment, the correction lens 46 easily collimates the light from the lower small lens 71, and the aberration of the correction lens 46 can be reduced.

In addition, the light emitting device 1 of the present embodiment includes two large lenses, that is, the lower large lens 81 provided on the back surface S2 of the substrate 51 and the upper large lens 82 provided on the front surface S3 of the lens film 56. Therefore, according to the present embodiment, the function of the correction lens 46 can be carried by these large lenses. For example, light can be collimated by only the lower small lens 71, the lower large lens 81, and the upper large lens 82 without using the correction lens 46, and the number of correction lenses 46 used together with the lower small lens 71, the lower large lens 81, and the upper large lens 82 for collimating light can be reduced. Accordingly, the light emitting device 1 can be reduced in size or height. For example, in a case where the correction lens 46 is unnecessary, the entire space for the correction lens 46 can be deleted, and in a case where the number of correction lenses 46 is reduced, a part of the space for the correction lens 46 can be deleted.

According to the present embodiment, for example, the performance of the ToF type distance measuring apparatus can be improved without providing the auxiliary lens 46 or a diffractive optical element (DOE) in the light-emitting side optical system 14. By not providing the diffractive optical element in the light-emitting side optical system 14, the light utilization efficiency of the distance measuring apparatus can be improved by, for example, 20 to 30%.

Note that the above-described operations and effects can also be obtained in a case where the lower small lens 71 is a lens other than a convex lens, in a case where the lower large lens 81 is a lens other than a convex lens, and in a case where the upper large lens 82 is a lens other than a convex lens. Details of such a configuration will be described later.

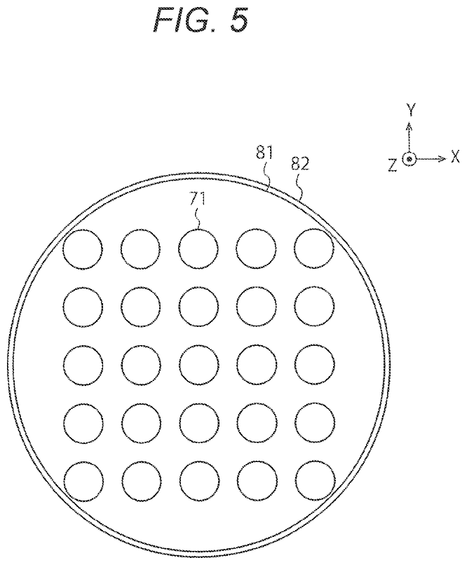

FIG. 5 is a plan view illustrating an example of a structure of the light emitting device 1 of the first embodiment.

FIG. 5 illustrates planar shapes of the lower small lens 71, the lower large lens 81, and the upper large lens 82. In plan view, the lower large lens 81 and the upper large lens 82 have substantially the same size, and the lower small lens 71 has a smaller size than the lower large lens 81 and the upper large lens 82. Specifically, the plurality of lower small lenses 71 is accommodated in the lower large lens 81 and in the upper large lens 82 in plan view. This makes it possible to dispose these lenses in a small region.

In FIG. 5, the lower small lenses 71 are arranged in a two-dimensional array, specifically, arranged in a square grid. The number of lower small lenses 71 in one lower large lens 81 is 25 in FIG. 5, but may be other than 25. Further, the lower small lenses 71 may be arranged in a two-dimensional array in an arrangement other than the square grid arrangement.

### (2) Structure of Light Emitting Device 1 of Modification of First Embodiment

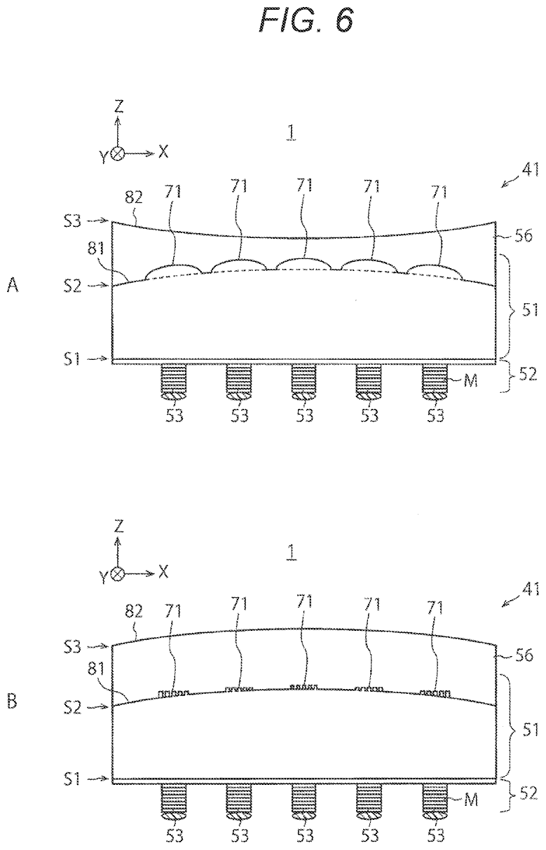

FIGS. 6 to 9 are cross-sectional views illustrating a structure of the light emitting device 1 of a modification of the first embodiment.

In the modification illustrated in A of FIG. 6, the lower small lens 71 is a convex lens, the lower large lens 81 is a convex lens, and the upper large lens 82 is a concave lens. According to the present modification, light can be focused by the lower small lens 71 and the lower large lens 81, and light can be diffused by the upper large lens 82.

In the modification illustrated in B of FIG. 6, the lower small lens 71 is a binary lens, the lower large lens 81 is a convex lens, and the upper large lens 82 is a convex lens. In this way, the lower small lens 71, the lower large lens 81, or the upper large lens 82 may be a binary lens. Note that the height of the upper end of the protruding portion of each lower small lens 71 (binary lens) with respect to the upper surface of the lower large lens 81 (convex lens), that is, the thickness of the protruding portion in the Z direction may be the same between the protruding portions, or may be different between the protruding portions.

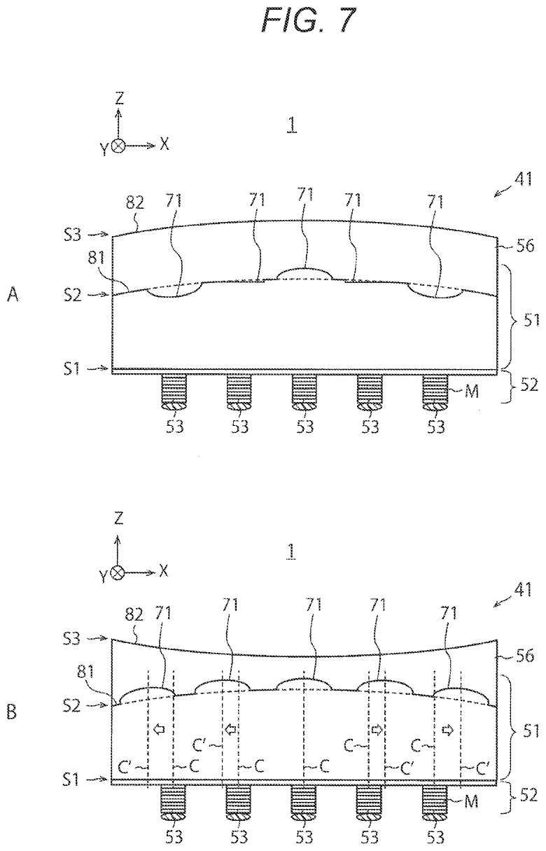

In the modification illustrated in A of FIG. 7, the lower small lens 71 is a convex lens, a concave lens, or a flat lens, the lower large lens 81 is a convex lens, and the upper large lens 82 is a convex lens. In this way, the lower small lens 71, the lower large lens 81, or the upper large lens 82 may be a flat lens. The concave lens has a concave front surface, and the convex lens has a convex front surface, whereas the flat lens has a flat front surface. Further, the lower small lens 71 may include two or more types of lenses. Note that the upper surface of the lower small lens 71, which is a flat lens, may protrude or be recessed with respect to the upper surface of the lower large lens 81, which is a convex lens, or may coincide with the upper surface of the lower large lens 81, which is a convex lens.

In the modification illustrated in B of FIG. 7, the lower small lens 71 is a convex lens, the lower large lens 81 is a convex lens, and the upper large lens 82 is a concave lens. Furthermore, the position of each lower small lens 71 is shifted from the position indicated by line C to the position indicated by line C′. Line C indicates the position of each lower small lens 71 in a case where the lower small lenses 71 are disposed at equal intervals. Therefore, the interval between lines C adjacent to each other is constant. On the other hand, line C′ indicates the position of each lower small lens 71 in a case where the lower small lens 71 is disposed to be shifted to the opposite side of the optical center A (FIG. 4) from line C. In the present modification, the distance between line C and line C′ in each lower small lens 71 increases with the distance from the optical center A. This makes it possible to reduce the aberration of the correction lens 46.

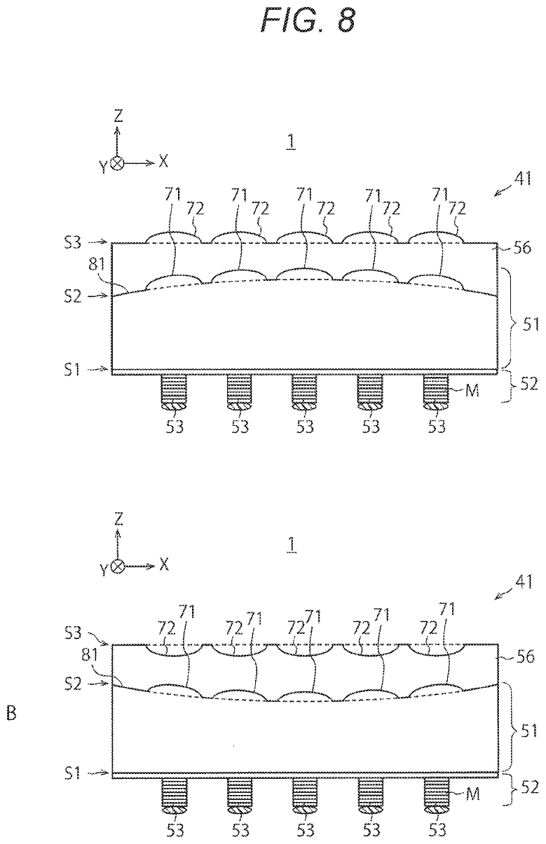

The light emitting device 1 of the modification illustrated in A of FIG. 8 includes a plurality of upper small lenses 72 instead of the upper large lens 82. Each upper small lens 72 is provided on the front surface S3 of the lens film 56 as a part of the lens film 56. The upper small lens 72 of the present modification is a small convex lens protruding in the +Z direction on the front surface S3 of the lens film 56. Similarly to the light emitting element 53, the upper small lenses 72 are arranged in a two-dimensional array. The light emitting element 53 and the upper small lens 72 of the present modification have a correspondence ratio of 1:1, and each upper small lens 72 is disposed in the +Z direction of one light emitting element 53. The upper small lens 72 is an example of a rear lens of the present disclosure.

The light emitted from the plurality of light emitting elements 53 passes through the substrate 51 from the front surface S1 to the back surface S2, and enters the plurality of lower small lenses 71 and the lower large lens 81. For example, the light emitted from each light emitting element 53 enters the corresponding lower small lens 71. The light having passed through the lower small lenses 71 and the lower large lens 81 enters the upper small lenses 72. For example, light that has passed through each lower small lens 71 enters the corresponding upper small lens 72. The light having passed through the upper small lens 72 enters the correction lens 46 (FIG. 2). In the present modification, the lower small lens 71, the lower large lens 81, the upper small lens 72, and the correction lens 46 focus the light from the light emitting element 53, and further collimate the light into parallel light. Note that, in a case where light can be sufficiently collimated by only the lower small lens 71, the lower large lens 81, and the upper small lens 72, the correction lens 46 may not be provided in the light emitting device 1.

The upper small lens 72 of the present modification may, for example, be disposed similarly to the lower small lens 71 of FIG. 5. That is, the plurality of upper small lenses 72 may be accommodated in the lower large lens 81 in plan view. This makes it possible to dispose these lenses in a small region.

In the modification illustrated in B of FIG. 8, the lower small lens 71 is a convex lens, the lower large lens 81 is a concave lens, and the upper small lens 72 is a concave lens. According to the present modification, light can be focused by the lower small lens 71, and light can be diffused by the lower large lens 81 and the upper small lens 72.

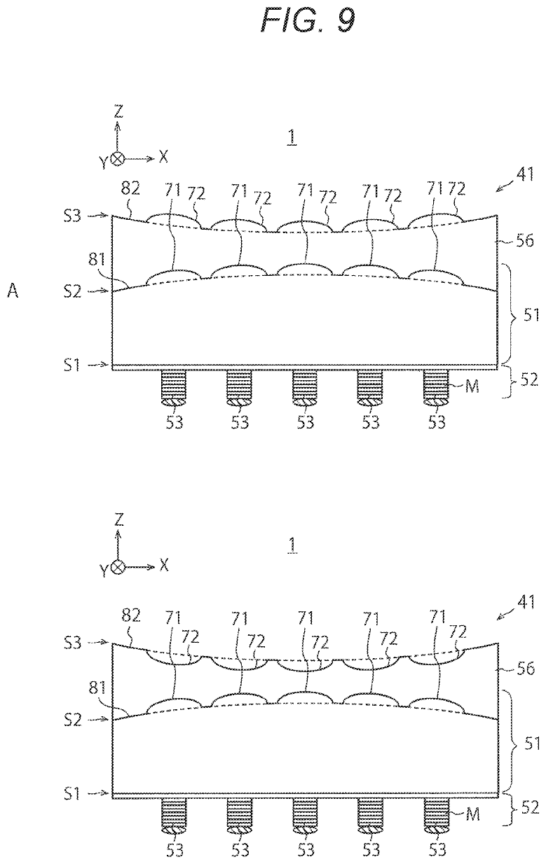

The light emitting device 1 of the modification illustrated in A of FIG. 9 includes both the plurality of upper small lenses 72 and the upper large lens 82. The upper small lens 72 and the upper large lens 82 are provided on the front surface S3 of the lens film 56 as a part of the lens film 56. The upper large lens 82 of the present modification is a large concave lens protruding in the −Z direction on the front surface S3 of the lens film 56, and the upper small lens 72 of the present modification is a small convex lens protruding in the +Z direction on the front surface of the lower large lens 81 in the front surface S3 of the lens film 56. Therefore, in the present modification, a part of the front surface of the upper large lens 82 constitutes the front surface of the upper small lens 72. The upper small lens 72 and the upper large lens 82 are examples of a rear lens of the present disclosure. Further, the upper small lens 72 is an example of a third lens of the present disclosure, and the upper large lens 82 is an example of a fourth lens of the present disclosure.

The light emitted from the plurality of light emitting elements 53 passes through the substrate 51 from the front surface S1 to the back surface S2, and enters the plurality of lower small lenses 71 and the lower large lens 81. For example, the light emitted from each light emitting element 53 enters the corresponding lower small lens 71. The light having passed through the lower small lens 71 and the lower large lens 81 enters the upper small lens 72 and the upper large lens 82. For example, light that has passed through each lower small lens 71 enters the corresponding upper small lens 72. The light having passed through the upper small lens 72 and the upper large lens 82 enters the correction lens 46 (FIG. 2). In the present modification, the lower small lens 71, the lower large lens 81, the upper small lens 72, the upper large lens 82, and the correction lens 46 focus and diverge the light from the light emitting element 53, and further collimate the light into parallel light. Note that, in a case where light can be sufficiently collimated by only the lower small lens 71, the lower large lens 81, the upper small lens 72, and the upper large lens 82, the correction lens 46 may not be provided in the light emitting device 1.

The lower small lens 71 and the upper small lens 72 of the present modification may, for example, be disposed similarly to the lower small lens 71 of FIG. 5. That is, the plurality of lower small lenses 71 may be accommodated in the lower large lens 81 or the upper large lens 82 in plan view, and the plurality of upper small lenses 72 may be accommodated in the lower large lens 81 or the upper large lens 82 in plan view. This makes it possible to dispose these lenses in a small region.

In the modification illustrated in B of FIG. 9, the lower small lens 71 is a convex lens, the lower large lens 81 is a convex lens, the upper small lens 72 is a concave lens, and the upper large lens 82 is a concave lens. According to the present modification, light can be focused by the lower small lens 71 and the lower large lens 81, and light can be diffused by the upper small lens 72 and the upper large lens 82.

Note that, since the lower small lens 71 and the lower large lens 81 are provided near the light emitting element 53, the light path can be finely controlled. Therefore, according to the lower small lens 71 and the lower large lens 81, for example, the beam diameter and direction of light can be finely changed for each light emitting element 53. On the other hand, since the upper small lens 72 and the upper large lens 82 are provided far from the light emitting element 53, the light path can be largely controlled similarly to the correction lens 46. Therefore, according to the upper small lens 72 and the upper large lens 82, for example, a function similar to that of the correction lens 46 can be easily realized. Furthermore, by using both the lenses (the lower small lens 71 and the lower large lens 81) on the substrate 51 and the lenses (the upper small lens 72 and the upper large lens 82) on the lens film 56, both of the above effects can be obtained.

### (3) Method for Manufacturing Light Emitting Device 1 of First Embodiment

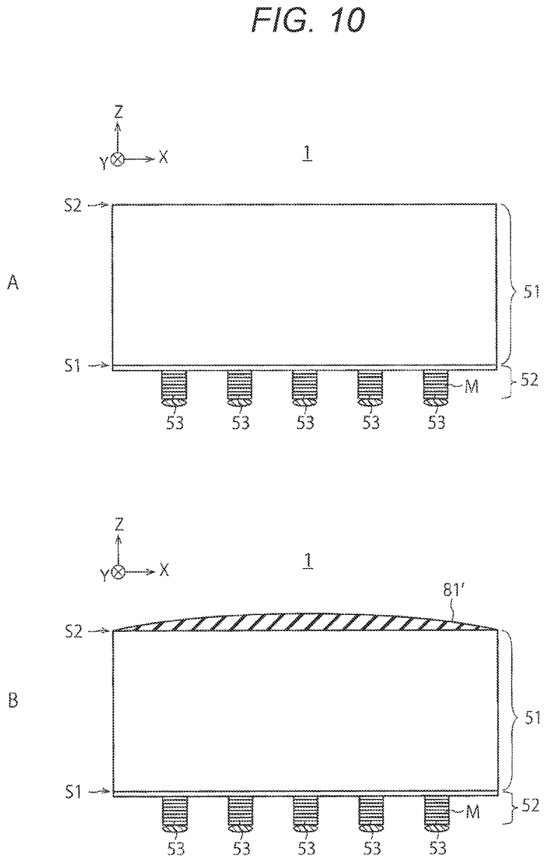

FIGS. 10 to 13 are cross-sectional views illustrating a method for manufacturing the light emitting device 1 of the first embodiment.

First, after the laminated film 52 and the light emitting element 53 are formed on the front surface S1 of the substrate 51 (A of FIG. 10), a resist film 81′ is formed on the back surface S2 of the substrate 51, and lithography and reflow baking of the resist film 81′ are performed (B of FIG. 10). As a result, the resist film 81′ is patterned by lithography, and the shape of the resist film 81′ is changed to a convex shape similar to that of the lower large lens 81 (convex lens) by reflow baking.

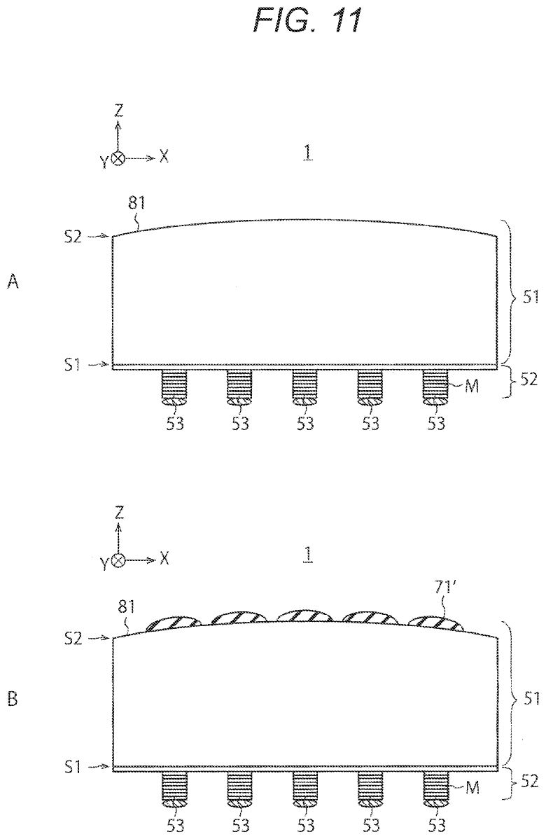

Next, the substrate 51 is processed by etching using the resist film 81′ as an etching mask (A of FIG. 11). As a result, the shape of the resist film 81′ is transferred to the substrate 51, and the lower large lens 81 is formed on the back surface S2 of the substrate 51. However, as will be described later, the height of the front surface of the lower large lens 81 is reduced by etching when the lower small lens 71 is formed.

Next, a resist film 71′ is formed on the back surface S2 of the substrate 51, and lithography and reflow baking of the resist film 71′ are performed (B of FIG. 11). As a result, the resist film 71′ is patterned by lithography, and the shape of the resist film 71′ is changed to a convex shape similar to that of the lower small lens 71 (convex lens) by reflow baking.

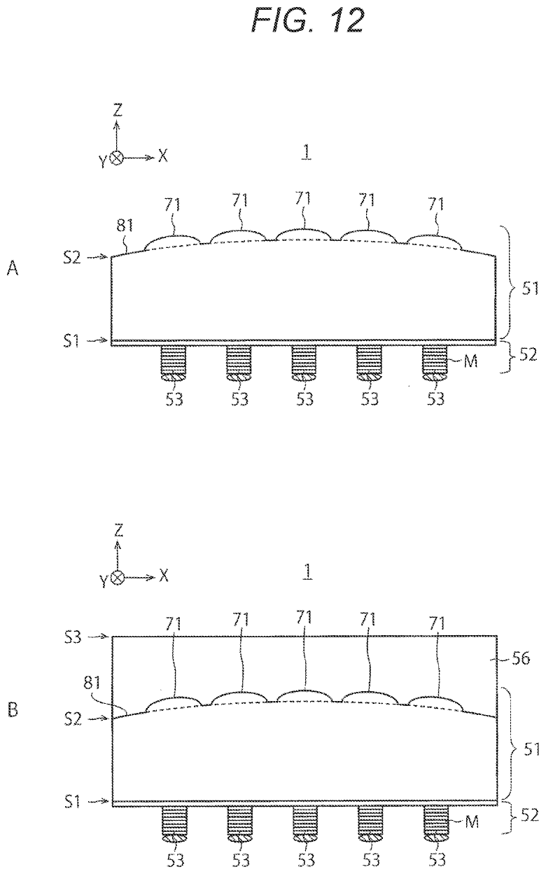

Next, the substrate 51 is processed by etching using the resist film 71′ as an etching mask (A of FIG. 12). As a result, the shape of the resist film 71′ is transferred to the substrate 51, and the lower small lens 71 is formed on the front surface of the lower large lens 81 in the back surface S2 of the substrate 51. In this way, in the present embodiment, the lower small lens 71 is formed after the formation of the lower large lens 81. The lower large lens 81 and the lower small lens 71 of the present embodiment are formed as a part of the substrate 51 by processing the back surface S2 of the substrate 51.

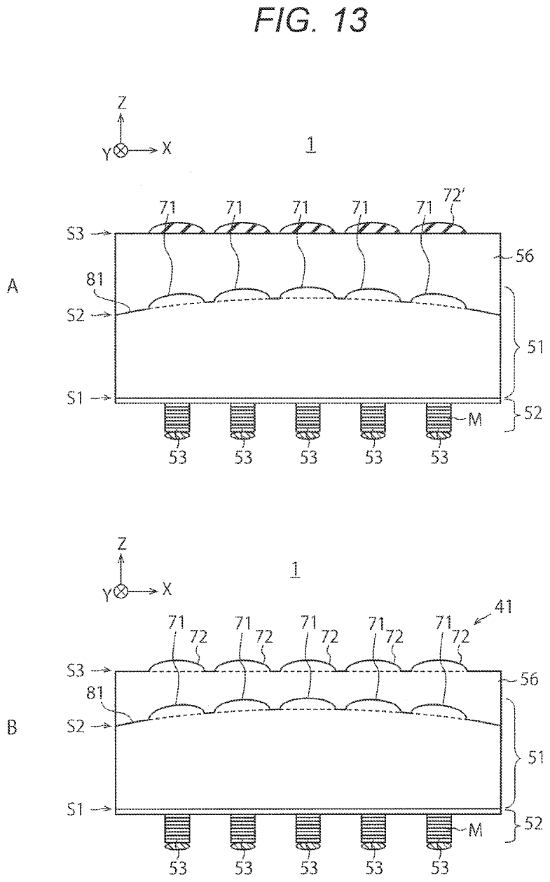

Next, after the lens film 56 on the back surface S2 of the substrate 51 is formed (B of FIG. 12), a resist film 72′ is formed on the front surface (upper surface) S3 of the lens film 56, and lithography and reflow baking of the resist film 72′ are performed (A of FIG. 13). As a result, the resist film 72′ is patterned by lithography, and the shape of the resist film 72′ is changed to a convex shape similar to that of the upper small lens 72 (convex lens) by reflow baking.

Next, the lens film 56 is processed by etching using the resist film 72′ as an etching mask (B of FIG. 13). As a result, the shape of the resist film 72′ is transferred to the lens film 56, and the upper small lens 72 is formed on the front surface S3 of the lens film 56. The upper small lens 72 of the present embodiment is formed as a part of the lens film 56 by processing the front surface S3 of the lens film 56. Thus, the semiconductor device illustrated in A of FIG. 8 is manufactured.

Note that, in steps illustrated in A of FIG. 11 to B of FIG. 13, a concave lens, a flat lens, or a binary lens may be formed as at least one of the lower large lens 81, the lower small lens 71, or the upper small lens 72. In addition, the upper large lens 82 may be formed in the lens film 56 instead of the upper small lens 72.

### (4) Method for Manufacturing Light Emitting Device 1 of Modification of First Embodiment

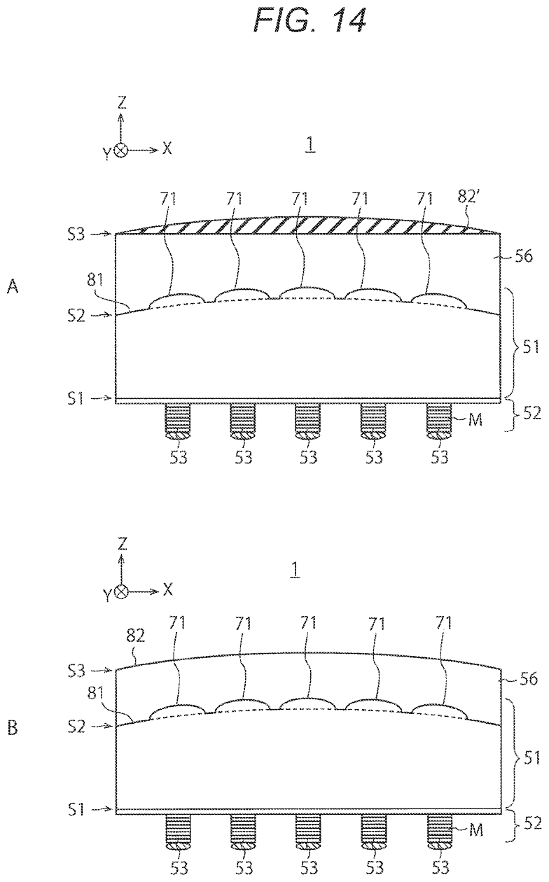

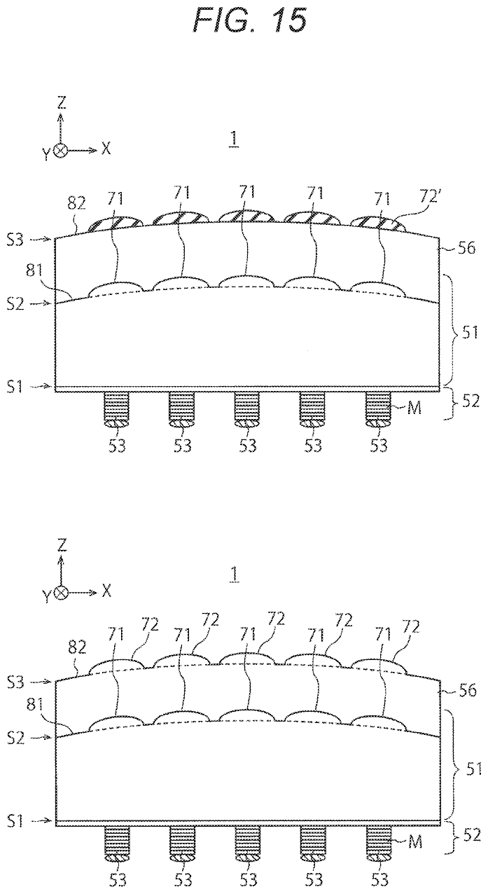

FIGS. 14 and 15 are cross-sectional views illustrating a method for manufacturing the light emitting device 1 of a modification of the first embodiment.

First, after the steps of A of FIG. 11 to B of FIG. 12 are performed, a resist film 82′ is formed on the front surface (upper surface) S3 of the lens film 56, and lithography and reflow baking of the resist film 82′ are performed (A of FIG. 14). As a result, the resist film 82′ is patterned by lithography, and the shape of the resist film 82′ is changed to a convex shape similar to that of the upper large lens 82 (convex lens) by reflow baking.

Next, the lens film 56 is processed by etching using the resist film 82′ as an etching mask (B of FIG. 14). As a result, the shape of the resist film 82′ is transferred to the lens film 56, and the upper large lens 82 is formed on the front surface S3 of the lens film 56. However, as will be described later, the height of the front surface of the upper large lens 82 is reduced by etching when the upper small lens 72 is formed.

Next, a resist film 72′ is formed on the front surface S3 of the lens film 56, and lithography and reflow baking of the resist film 72′ are performed (A of FIG. 15). As a result, the resist film 72′ is patterned by lithography, and the shape of the resist film 72′ is changed to a convex shape similar to that of the upper small lens 72 (convex lens) by reflow baking.

Next, the lens film 56 is processed by etching using the resist film 72′ as an etching mask (B of FIG. 15). As a result, the shape of the resist film 72′ is transferred to the lens film 56, and the upper small lens 72 is formed on the front surface of the upper large lens 82 in the front surface S3 of the lens film 56. In this way, in the present embodiment, the upper small lens 72 is formed after the formation of the upper large lens 82. The upper large lens 82 and the upper small lens 72 of the present embodiment are formed as a part of the lens film 56 by processing the front surface S3 of the lens film 56. Thus, a semiconductor device similar to the semiconductor device illustrated in A or B of FIG. 9 is manufactured.

Note that, in steps illustrated in A of FIG. 14 to B of FIG. 15, a concave lens, a flat lens, or a binary lens may be formed as at least one of the lower large lens 81, the lower small lens 71, the upper large lens 82, or the upper small lens 72.

Further, in the steps illustrated in A of FIG. 11 to FIG. 15B, the lower large lens 81 and the lower small lens 71 may be formed simultaneously, or the upper large lens 82 and the upper small lens 72 may be formed simultaneously. For example, if a resist film is formed on the back surface S2 of the substrate 51, the resist film is processed into a shape similar to that of the lower large lens 81 and the lower small lens 71, and the substrate 51 is processed using the resist film, the lower large lens 81 and the lower small lens 71 can be simultaneously formed on the substrate 51. The simultaneous formation of such lenses has an advantage that the lower large lens 81 and the lower small lens 71 can be formed with a small number of steps. On the other hand, the sequential formation of the lenses as described above has an advantage that the lower large lens 81 and the lower small lens 71 can be precisely formed. This also applies to a case where the upper large lens 82 and the upper small lens 72 are simultaneously formed.

In addition, these lenses may be formed by methods other than lithography, reflow baking, and etching. These lenses may be formed by, for example, implants, or may be formed by grayscale lithography and etching.

As described above, the light emitting device 1 of the present embodiment includes one or more front lenses provided on the substrate 51 and one or more rear lenses provided on the lens film 56, and the front lens includes the lower small lens 71 and the lower large lens 81, or the rear lens includes the upper small lens 72 and the upper large lens 82. Therefore, according to the present embodiment, for example, the light from the plurality of light emitting elements 53 can be suitably collimated using the front lens and the rear lens, and the light from the plurality of light emitting elements 53 can be suitably shaped. For example, light can be collimated by only the front lens and the rear lens without using the correction lens 48, or the number of correction lenses 48 used together with the front lens and the rear lens for collimating light can be reduced. As a result, the light emitting device 1 can be reduced in size or height.

Note that the light emitting device 1 of the present embodiment may include only one of the lower small lens 71 and the lower large lens 81 as the front lens, and may include both the upper small lens 72 and the upper large lens 82 as the rear lens. Such a light emitting device 1 can be manufactured, for example, by omitting the steps related to the resist film 71′ or the resist film 81′ in the steps of A of FIG. 14 when performing the steps of A of FIG. 14 to B of FIG. 15.

### Second Embodiment

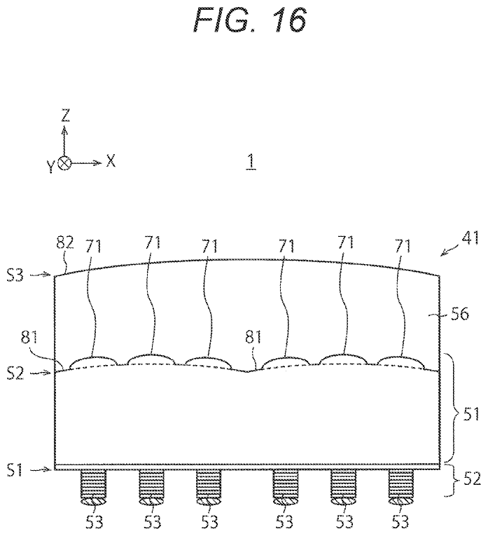

FIG. 16 is a cross-sectional view illustrating a structure of a light emitting device 1 of a second embodiment.

In the present embodiment, the light emitting element 53 and the lower large lens 81 have a correspondence ratio of Na:1 (Na is an integer of 2 or more), the light emitting element 53 and the upper large lens 82 have a correspondence ratio of Nb:1 (Nb is an integer of 2 or more), and Na and Nb are integers different from each other. Accordingly, the lower large lens 81 can collectively shape the light from the Na light emitting elements 53, and the upper large lens 82 can collectively shape the light from the Nb light emitting elements 53. According to the present embodiment, the unit of the number of light emitting elements 53 that collectively shape light can be made different between the lower large lens 81 and the upper large lens 82.

In the present embodiment, the value of Nb is set to be larger than the value of Na. Accordingly, the unit of the number of light emitting elements 53 that collectively shape light can be made larger in the upper large lens 82 than in the lower large lens 81. According to the present embodiment, for example, light can be finely shaped by the lower large lens 81, and then light can be largely shaped by the upper large lens 82. Note that, depending on the purpose of use of the light emitting device 1, the value of Nb may be set to be smaller than the value of Na.

Note that the light emitting device 1 of the present embodiment may include not only the lower small lens 71, the lower large lens 81, and the upper large lens 82 but also the upper small lens 72. In addition, the light emitting device 1 of the present embodiment may include the upper small lens 72 instead of the lower small lens 71.

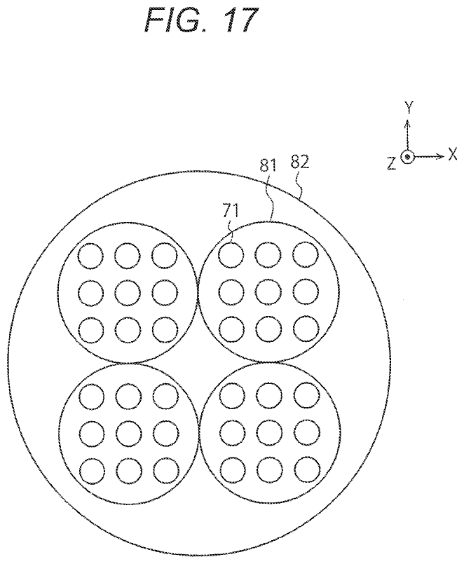

FIG. 17 is a plan view illustrating an example of a structure of the light emitting device 1 of the second embodiment.

FIG. 17 illustrates planar shapes of the lower small lens 71, the lower large lens 81, and the upper large lens 82. In plan view, the lower large lens 81 has a smaller size than the upper large lens 82, and the lower small lens 71 has a smaller size than the lower large lens 81. Specifically, the plurality of lower large lenses 81 is accommodated in one upper large lens 82 in plan view, and the plurality of lower small lenses 71 is accommodated in one lower large lens 81 in plan view.

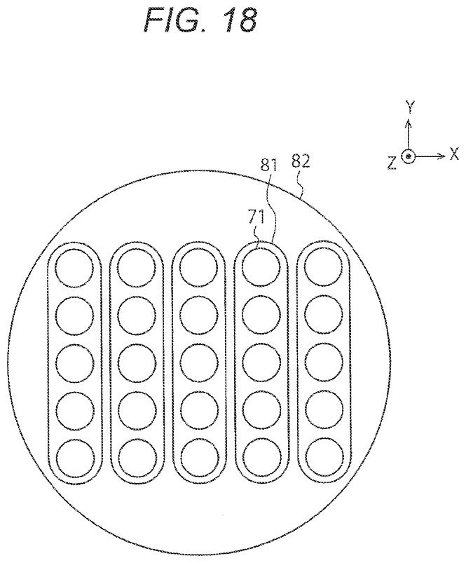

FIG. 18 is a plan view illustrating another example of the structure of the light emitting device 1 of the second embodiment.

FIG. 18 illustrates planar shapes of the lower small lens 71, the lower large lens 81, and the upper large lens 82 similarly to FIG. 17. However, the lower large lens 81 of the present modification has a planar shape extending linearly in the Y direction. Such a structure can be applied, for example, to a case where the plurality of light emitting elements 53 is caused to emit light for each line. In this case, the light can be suitably shaped by causing these light emitting elements 53 to emit light for each line and shaping linear light with the linear lower large lens 81. Note that the lower large lens 81 may have a planar shape extending linearly in the X direction instead of the Y direction.

According to the present embodiment, by making the sizes of the lower large lens 81 and the upper large lens 82 different from each other, more various types of light can be shaped.

### Third Embodiment

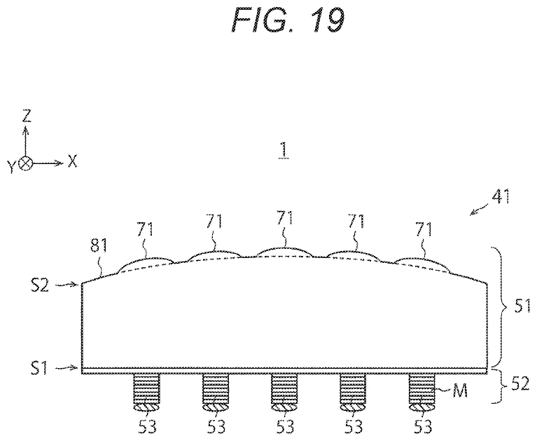

FIG. 19 is a cross-sectional view illustrating a structure of the light emitting device 1 of a third embodiment.

The light emitting device 1 of the present embodiment includes the substrate 51 but does not include the lens film 56. Therefore, the light emitting device 1 of the present embodiment includes the lower small lens 71 and the lower large lens 81, but does not include the upper small lens 72 and the upper large lens 82. The lower small lens 71 is an example of a fifth lens of the present disclosure, and the lower large lens 81 is an example of a sixth lens of the present disclosure.

For example, in a case where light can be sufficiently shaped only by the lower small lens 71, the lower large lens 81, and the correction lens 46 (FIG. 2), the structure of the present embodiment may be employed. This makes it possible to omit the step of forming the lens film 56. Furthermore, in a case where light can be sufficiently shaped only by the lower small lens 71 and the lower large lens 81, the correction lens 46 may be deleted from the light emitting device 1 of the present embodiment. Accordingly, the light emitting device 1 can be reduced in size or height.

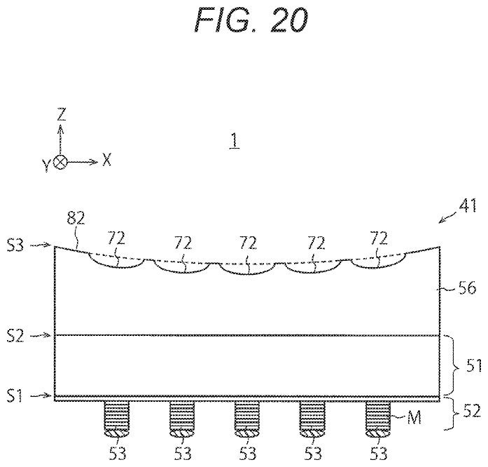

FIG. 20 is a cross-sectional view illustrating a structure of the light emitting device 1 of a modification of the third embodiment.

The light emitting device 1 of the present modification includes the upper small lens 72 and the upper large lens 82 on the front surface S3 of the lens film 56, but does not include the lower small lens 71 and the lower large lens 81 on the back surface S2 of the substrate 51. The upper small lens 72 is an example of a fifth lens of the present disclosure, and the upper large lens 82 is an example of a sixth lens of the present disclosure.

For example, in a case where light can be sufficiently shaped only by the upper small lens 72, the upper large lens 82, and the correction lens 46 (FIG. 2), and in a case where it is not desired to process the substrate 51, the structure of the present modification may be employed. In a case where the substrate 51 is a GaAs substrate, the GaAs substrate can improve the performance of the light emitting element 53, but may be damaged during etching. In this case, if a lens is formed on the lens film 56 instead of forming a lens on the substrate 51, it is possible to avoid damage to the substrate 51 during etching. Furthermore, in a case where light can be sufficiently shaped only by the upper small lens 72 and the upper large lens 82, the correction lens 46 may be deleted from the light emitting device 1 of the present embodiment. Accordingly, the light emitting device 1 can be reduced in size or height.

According to the present embodiment, by forming the lens only on one of the substrate 51 and the lens film 56, for example, the number of manufacturing steps of the light emitting device 1 can be reduced, and damage to the substrate 51 can be suppressed.

Note that the light emitting device 1 of the first to third embodiments is used as a light source of a distance measuring apparatus, but may be used in other modes. For example, the light emitting device 1 of these embodiments may be used as a light source of an optical instrument such as a printer, or may be used as a lighting device.

Although the embodiments of the present disclosure have been described above, these embodiments may be implemented with various modifications without departing from the gist of the present disclosure. For example, two or more embodiments may be implemented in combination.

Note that the present disclosure can also have the following configurations.

(1) A light emitting device including:
a substrate;
a plurality of light emitting elements provided on a first surface side of the substrate;
one or more front lenses which are provided on a second surface side of the substrate and on which light emitted from the plurality of light emitting elements is incident; and
one or more rear lenses which are provided on a film provided on a front surface of the first lens and on which light having passed through the first lens is incident,
in which the front lens includes a first lens and a second lens, and a part of a front surface of the second lens constitutes a front surface of the first lens, or
the rear lens includes a third lens and a fourth lens, and a part of a front surface of the fourth lens constitutes a front surface of the third lens.

(2) The light emitting device according to (1),
in which the first lens is provided in the second lens in plan view, or
the third lens is provided in the fourth lens in plan view.

(3) The light emitting device according to (1), in which the light emitting element and the first or third lens have a correspondence ratio of 1:1, and the light emitting element and the second or fourth lens have a correspondence ratio of N:1 (N is an integer of 2 or more).

(4) The light emitting device according to (1), in which the front lens includes the first lens and the second lens, and the rear lens includes the third lens and the fourth lens.

(5) The light emitting device according to (1), in which the front lens includes a lens having a correspondence ratio of Na:1 with the light emitting element, and the rear lens includes a lens having a correspondence ratio of Nb:1 with the light emitting element (Na and Nb are integers of 2 or more different from each other).

(6) The light emitting device according to (5), in which the value of Nb is larger than the value of Na.

(7) The light emitting device according to (1), in which the first, second, third, or fourth lens includes at least one of a convex lens, a concave lens, a flat lens, or a binary lens.

(8) The light emitting device according to (1), in which the front lens is provided on the second surface of the substrate as a part of the substrate.

(9) The light emitting device according to (1), in which the substrate is a semiconductor substrate containing gallium (Ga) and arsenic (As).

(10) The light emitting device according to (1), in which light emitted from the plurality of light emitting elements passes through the substrate from the first surface to the second surface and enters the front lens.

(11) The light emitting device according to (1), in which the first surface of the substrate is a front surface of the substrate, and the second surface of the substrate is a back surface of the substrate.

(12) The light emitting device according to (1), further including a drive device that is provided on the first surface side of the substrate via the plurality of light emitting elements and drives the plurality of light emitting elements.

(13) The light emitting device according to (12), in which the drive device drives the plurality of light emitting elements for each light emitting element.

(14) A light emitting device including:
a substrate;
a plurality of light emitting elements provided on a first surface side of the substrate; and
one or more lenses which are provided on a second surface side of the substrate and on which light emitted from the plurality of light emitting elements is incident,
in which the lens includes a fifth lens and a sixth lens, and a part of a front surface of the sixth lens constitutes a front surface of the fifth lens.

(15) The light emitting device according to (14), in which the fifth and sixth lenses are provided on the second surface of the substrate as a part of the substrate.

(16) The light emitting device according to (14), in which the fifth and sixth lenses are provided on a film provided on the second surface side of the substrate.

(17) A method for manufacturing a light emitting device, the method including:
forming a plurality of light emitting elements on a first surface side of a substrate;
forming, on a second surface side of the substrate, one or more front lenses on which light emitted from the plurality of light emitting elements is incident; and
forming, on a film provided on a front surface of the front lens, one or more rear lenses on which light having passed through the front lens is incident,
in which the front lens includes a first lens and a second lens, and is formed such that a part of a front surface of the second lens constitutes a front surface of the first lens, or
the rear lens includes a third lens and a fourth lens, and is formed such that a part of a front surface of the fourth lens constitutes a front surface of the third lens.

(18) The method for manufacturing a light emitting device according to (17),
in which the first lens is formed after formation of the second lens, or
the third lens is formed after formation of the fourth lens.

(19) The method for manufacturing a light emitting device according to (17),
in which the first lens is formed simultaneously with the second lens, or
the third lens is formed simultaneously with the fourth lens.

(20) The method for manufacturing a light emitting device according to (17), in which the front lens is formed as a part of the substrate by processing the second surface of the substrate.

### REFERENCE SIGNS LIST

1 Light emitting device
2 Imaging device
3 Control device
11 Light emitting unit
12 Drive circuit
13 Power supply circuit
14 Light-emitting side optical system
21 Image sensor
22 Image processing unit
23 Imaging side optical system
31 Distance measuring unit
41 LD chip
42 LDD substrate
43 Mounting substrate
44 Heat dissipation substrate
45 Correction lens holding portion
46 Correction lens
47 Wiring
48 Bump
51 Substrate
52 Laminated film
53 Light emitting element
54 Anode electrode
55 Cathode electrode
56 Lens film
61 Substrate
62 Connection pad
71 Lower small lens
71′ Resist film
72 Upper small lens
72′ Resist film
81 Lower large lens
81′ Resist film
82 Upper large lens
82′ Resist film

What is claimed is:

1. A light emitting device, comprising:
a substrate;
a plurality of light emitting elements provided on a first surface side of the substrate;
one or more front lenses which are provided on a second surface side of the substrate and on which light emitted from the plurality of light emitting elements is incident; and
one or more rear lenses which are provided on a film provided on a front surface of the first lens and on which light having passed through the first lens is incident,
wherein the front lens includes a first lens and a second lens, and a part of a front surface of the second lens constitutes a front surface of the first lens, or
the rear lens includes a third lens and a fourth lens, and a part of a front surface of the fourth lens constitutes a front surface of the third lens.

2. The light emitting device according to claim 1,
wherein the first lens is provided in the second lens in plan view, or
the third lens is provided in the fourth lens in plan view.

3. The light emitting device according to claim 1, wherein the light emitting element and the first or third lens have a correspondence ratio of 1:1, and the light emitting element and the second or fourth lens have a correspondence ratio of N:1 (N is an integer of 2 or more).

4. The light emitting device according to claim 1, wherein the front lens includes the first lens and the second lens, and the rear lens includes the third lens and the fourth lens.

5. The light emitting device according to claim 1, wherein the front lens includes a lens having a correspondence ratio of Na:1 with the light emitting element, and the rear lens includes a lens having a correspondence ratio of Nb:1 with the light emitting element (Na and Nb are integers of 2 or more different from each other).

6. The light emitting device according to claim 5, wherein the value of Nb is larger than the value of Na.

7. The light emitting device according to claim 1, wherein the first, second, third, or fourth lens includes at least one of a convex lens, a concave lens, a flat lens, or a binary lens.

8. The light emitting device according to claim 1, wherein the front lens is provided on the second surface of the substrate as a part of the substrate.

9. The light emitting device according to claim 1, wherein the substrate is a semiconductor substrate containing gallium (Ga) and arsenic (As).

10. The light emitting device according to claim 1, wherein light emitted from the plurality of light emitting elements passes through the substrate from the first surface to the second surface and enters the front lens.

11. The light emitting device according to claim 1, wherein the first surface of the substrate is a front surface of the substrate, and the second surface of the substrate is a back surface of the substrate.

12. The light emitting device according to claim 1, further comprising a drive device that is provided on the first surface side of the substrate via the plurality of light emitting elements and drives the plurality of light emitting elements.

13. The light emitting device according to claim 12, wherein the drive device drives the plurality of light emitting elements for each light emitting element.

14. A light emitting device, comprising:
a substrate;
a plurality of light emitting elements provided on a first surface side of the substrate; and
one or more lenses which are provided on a second surface side of the substrate and on which light emitted from the plurality of light emitting elements is incident,
wherein the lens includes a fifth lens and a sixth lens, and a part of a front surface of the sixth lens constitutes a front surface of the fifth lens.

15. The light emitting device according to claim 14, wherein the fifth and sixth lenses are provided on the second surface of the substrate as a part of the substrate.

16. The light emitting device according to claim 14, wherein the fifth and sixth lenses are provided on a film provided on the second surface side of the substrate.

17. A method for manufacturing a light emitting device, the method comprising:
forming a plurality of light emitting elements on a first surface side of a substrate;
forming, on a second surface side of the substrate, one or more front lenses on which light emitted from the plurality of light emitting elements is incident; and
forming, on a film provided on a front surface of the front lens, one or more rear lenses on which light having passed through the front lens is incident,
wherein the front lens includes a first lens and a second lens, and is formed such that a part of a front surface of the second lens constitutes a front surface of the first lens, or
the rear lens includes a third lens and a fourth lens, and is formed such that a part of a front surface of the fourth lens constitutes a front surface of the third lens.

18. The method for manufacturing a light emitting device according to claim 17,
wherein the first lens is formed after formation of the second lens, or
the third lens is formed after formation of the fourth lens.

19. The method for manufacturing a light emitting device according to claim 17,
wherein the first lens is formed simultaneously with the second lens, or
the third lens is formed simultaneously with the fourth lens.

20. The method for manufacturing a light emitting device according to claim 17, wherein the front lens is formed as a part of the substrate by processing the second surface of the substrate.
